(19) United States
(12) Patent Application Publication
(10) Pub. No.: US 2010/0133722 A1
(43) Pub. Date: Jun. 3, 2010

(54) SEMICONDUCTOR DEVICE MANUFACTURING METHOD

(75) Inventor: Mitsuhisa Watanabe, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc, Tokyo (JP)

(21) Appl. No.: 12/623,071

(22) Filed: Nov. 20, 2009

(30) Foreign Application Priority Data
Dec. 3, 2008 (JP) 2008-308835

(51) Int. Cl. H01L 21/56

(52) U.S. Cl. 264/272.17; 438/127; 257/E21.502

(57) ABSTRACT

A method for a semiconductor device includes the following processes. A first seal layer is formed in a cavity of a first mold, the first seal layer being in a liquid state. A second seal layer is formed over the first seal layer while the first seal layer is kept in the liquid state, and the second seal layer is in a liquid state. A semiconductor chip on a wiring board fixed on a second mold is immersed into the second seal layer. The first and second seal layers are thermally cured.

### BACKGROUND OF THE INVENTION

1. Field of the Invention

The present invention relates to a semiconductor device manufacturing method.

Priority is claimed on Japanese Patent Application No. 2008-308835, filed Dec. 3, 2008, the content of which is incorporated herein by reference.

2. Description of the Related Art

Conventionally, a BGA (Ball Grid Array)-type semiconductor device includes: a wiring board having a top surface on which multiple connection pads are provided, and a bottom surface on which multiple lands electrically connected to the connection pads are provided; a semiconductor chip provided on the top surface of the wiring board; wires electrically connecting electrode pads on the semiconductor chip and the connection pads on the wiring board; a seal which is made of an insulating resin and covers at least the semiconductor chip and the wires; and external terminals, such as solder balls, provided on the lands.

Such a BGA semiconductor device warps due to the difference in values of thermal expansion coefficients between a wiring board and a seal resin. Consequently, solder balls are not correctly connected upon a secondary mounting of the semiconductor device onto a motherboard.

Additionally, a BGA-type semiconductor device to be used for a PoP (Package on Package) cannot be electrically connected to another semiconductor device to be stacked when the semiconductor device and the other semiconductor device warp in the opposite directions.

Further, the difference in values of thermal expansion coefficients between the wiring board and the semiconductor chip causes stress to be applied onto a periphery of the semiconductor chip, especially onto four corners thereof. Thereby, solder balls under the four corners crack, degrading the reliability of a secondary mounting of the semiconductor device.

The following related arts disclose methods of preventing such a semiconductor device from warping. Japanese Patent Laid-Open Publication Nos. 2006-269861 and 2007-66932 (hereinafter, “Patent Documents 1 and 2”) disclose a semiconductor device including: a lower board (wiring board); a semiconductor chip above the lower board; an intermediate member (seal) covering the semiconductor chip; and an upper board covering the intermediate member. The upper board has a thermal expansion coefficient substantially equal to that of the lower board.

Japanese Patent Laid-Open Publication No. 2006-286829 (hereinafter, “Patent Document 3”) discloses a semiconductor device including: a first resin (seal) covering a semiconductor chip on a wiring board to prevent deformations of bonding wires and corrosions of portions connecting the semiconductor chip and the wires; and a second resin (seal) covering the first resin and the wiring board to prevent the wiring board from warping.

Japanese Patent Laid-Open Publication Nos. H10-112515 and 2008-153601 (hereinafter, “Patent Documents 4 and 5”) disclose a semiconductor device including a first seal resin on a wiring board and a fiber-included second seal resin covering the first seal resin.

Concerning the semiconductor device disclosed in Patent Documents 1 and 2, the upper board is fixed on a mold for sealing and then a seal resin is filled into the mold, thereby requiring a new upper board to be prepared every time the type or the package size is changed, and therefore reducing versatility.

To apply the technique disclosed in Patent Documents 1 and 2 to a normal BGA semiconductor device having a face-up structure, sufficient clearances are necessary for wires, thereby making it difficult to reduce the thickness of the semiconductor device. Additionally, the upper board is necessary in addition to the seal resin, thereby increasing the costs.

Concerning the semiconductor device disclosed in Patent Document 3, two sealing processes are required for forming the first and second seals, thereby decreasing the manufacturing efficiency. Additionally, the seal resin is filled into a mold for sealing, thereby causing a biased distribution of the filler in the seal resin, and therefore causing the semiconductor device to warp.

Concerning the semiconductor device disclosed in Patent Documents 4 and 5, double the number of processes (forming a first resin, thermally curing the first resin, forming a second seal resin, and thermally curing the second seal resin) are required, thereby decreasing the manufacturing efficiency, and therefore increasing the costs.

Additionally, the first and second seal resins are formed by two sealing processes, thereby decreasing the connection strength of the first and second seal resins, and therefore causing a void between the first and second seal resins which might cause the package to crack in a reflow process.

Further, the second seal resin forcedly prevents the first seal resin from expanding, thereby causing the second seal resin to crack or to peel form the first seal resin.

Moreover, a MAP (Mold Array Process) is not used, and the two seal resins are formed for each semiconductor chip, thereby decreasing the manufacturing efficiency. Additionally, the thicknesses of the first and second seal resins are not uniform since the second seal resin covers the first seal resin in a trapezoidal shape, thereby unbalancing thermal expansion of the first and second seal resins.

### SUMMARY

In one embodiment, a method for a semiconductor device includes the following processes. A first seal layer is formed in a cavity of a first mold, the first seal layer being in a liquid state. A second seal layer is formed over the first seal layer while the first seal layer is kept in the liquid state, and the second seal layer is in a liquid state. A semiconductor chip on a wiring board fixed on a second mold is immersed into the second seal layer. The first and second seal layers are thermally cured.

In another embodiment, a method for a semiconductor device includes the following processes. A first seal layer is formed in a cavity of a first mold, the first seal layer being in a liquid state. A second seal layer is formed over the first seal layer while the first seal layer is kept in the liquid state, and the second seal layer is in a liquid state. A semiconductor chip on a wiring board fixed on a second mold is immersed into the second seal layer. The first and second seal layers are thermally cured.

In still another embodiment, a method for a semiconductor device includes the following processes. A first seal layer is formed in a cavity of a first mold, the first seal layer being in a liquid state. A second seal layer is formed over the first seal layer while the first seal layer is kept in the liquid state, and the second seal layer is in a liquid state.

Accordingly, a seal including two seal layers having different thermal expansion coefficients can be formed by one sealing process, thereby enhancing the manufacturing efficiency and reducing the manufacturing costs.

### BRIEF DESCRIPTION OF THE DRAWINGS

The above features and advantages of the present invention will be more apparent from the following description of certain preferred embodiments taken in conjunction with the accompanying drawings, in which:

FIGS. 1A to 1E are cross-sectional views indicative of a process flow illustrating a method of manufacturing a semiconductor device according to a first embodiment of the present invention;

FIGS. 2A to 2D are cross-sectional views indicative of a process flow illustrating a sealing process; and

FIG. 3 is a cross-sectional view illustrating a semiconductor device formed by the method according to the first embodiment.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

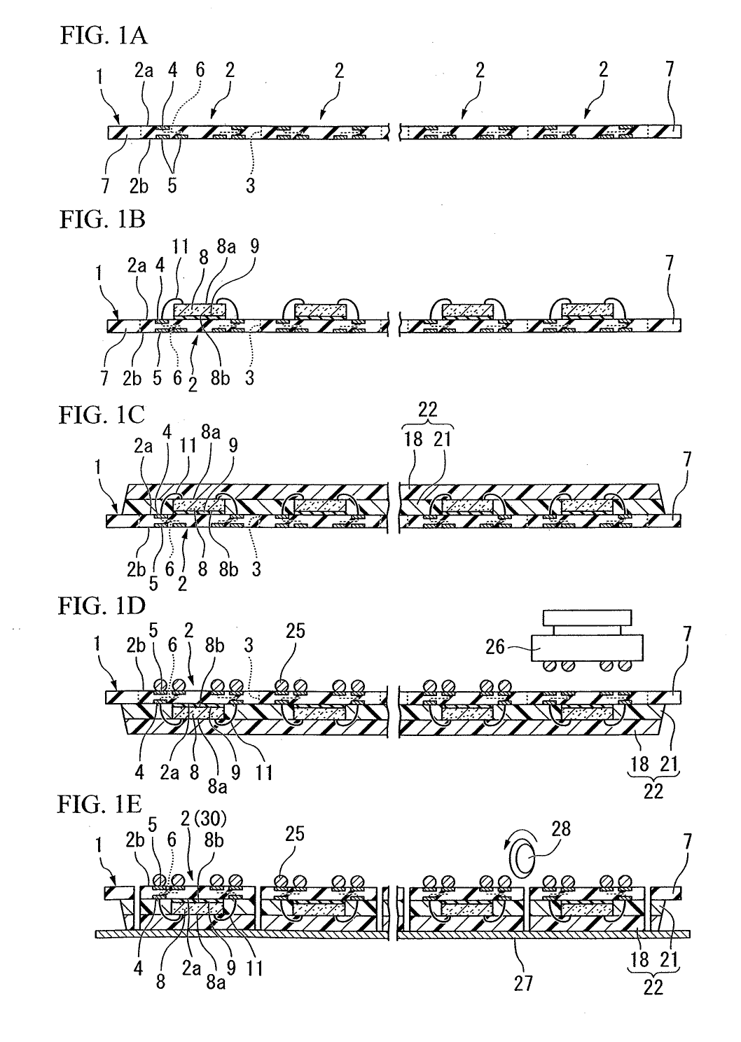

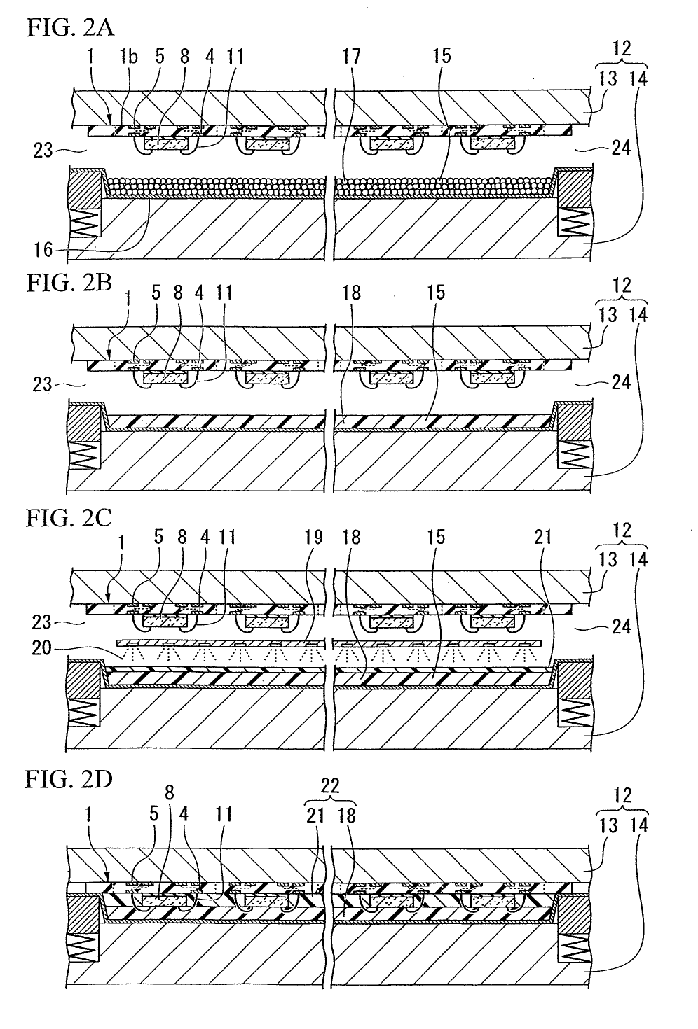

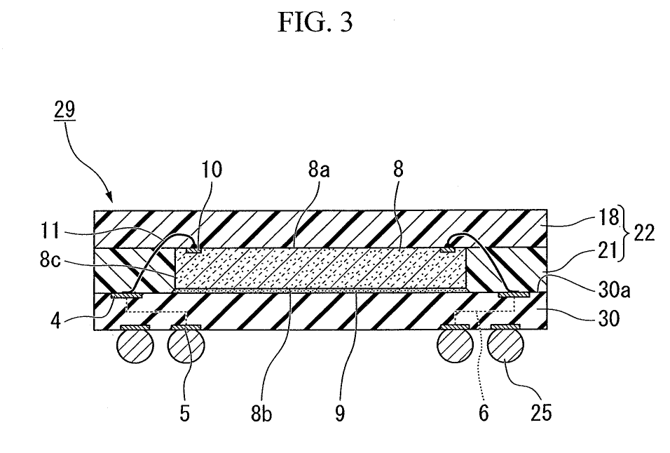

FIGS. 1A to 1E are cross-sectional views indicative of a process flow illustrating a method of manufacturing a semiconductor device according to a first embodiment of the present invention. FIGS. 2A to 2D are cross-sectional views indicative of a process flow illustrating a sealing process. FIG. 3 is a cross-sectional view illustrating a semiconductor device formed by the method according to the first embodiment.

As shown in FIG. 1A, a wiring motherboard 1 to be used for manufacturing a semiconductor device according to the first embodiment is processed by the MAP. The wiring motherboard 1 is rectangular in a plane view perpendicular to surfaces 2a and 2b thereof. Multiple element formation units 2 are provided in a matrix on the wiring motherboard 1. The element formation unit 2 will be a wiring board 30 after dicing the wiring motherboard 1 along the dicing lines 3.

The wiring motherboard 1 is a glass epoxy board having a thickness of, for example, 0.25 mm. Wires are provided on both surfaces 2a and 2b of the wiring motherboard 1. An insulating film (not shown), such as a solder resist film, partially covers the wires.

Multiple connection pads 4 are provided over the wires on the surface 2a uncovered by the solder resist film. Multiple lands 5 are provided in a grid over the wires on the surface 2b uncovered by the solder resist film. The connection pads 4 are electrically connected to the corresponding lands 5 using wires 6.

A frame 7 is provided surrounding the wiring motherboard 1. Positioning holes are provided at a given pitch in the frame 7 for transportation and positioning. Boundaries among the element formation units 2 are dicing lines 3. Thus, the wiring motherboard 1 shown in FIG. 1A is prepared.

Then, a surface 8b of a semiconductor chip 8 is fixed on substantially the center of the surface 2a of each element formation unit 2 of the wiring motherboard 1 using, for example, an insulating adhesive or a DAF (Die Attached Film), as shown in FIG. 1B. A predetermined circuit, such as a logic circuit or a memory circuit, is formed on the surface 8a of the semiconductor chip 8. Multiple electrode pads 10 are provided on a periphery of the semiconductor chip 8, as shown in FIG. 3.

After the semiconductor chip 8 is fixed on the element formation unit 2, the electrode pads 10 on the surface 8a of the semiconductor chip 8 are connected to the connection pads 4 on the wiring motherboard 1 using conductive wires 11 made of, for example, Au.

Specifically, one end of the wire 11 is melted so as to be in a ball shape, and then connected to the electrode pad 10 on the semiconductor chip 8 by ultrasonic thermocompression using a wire-bonding apparatus (not shown). Then, the wire 11 is made into a loop, and then the other edge is connected to the corresponding connection pad 4 by ultrasonic thermocompression.

Then, the surface 1b of the wiring motherboard 1 is held by suction on an upper mold 13 of a compression mold apparatus 12, as shown in FIG. 2A. In this case, a lower mold 14 of the compression mold apparatus 12 has a cavity 15. A predetermined amount of a granular seal resin 17 is provided into the cavity 15 through a film 16.

A resin having a thermal expansion coefficient of, for example, 12×10⁻⁶/° C. to 14×10⁻⁶/° C. is used for the seal resin 17. Preferably, an epoxy resin having a thermal expansion coefficient nearly equal to 13×10⁻⁶/° C., which is the thermal expansion coefficient of a glass epoxy wiring board, is used.

Then, the lower mold 14 is heated up to a predetermined temperature so that the granular seal resin 17 provided in the cavity 15 is melted to form a first resin layer 18 that is a melted liquid seal resin, as shown in FIG. 2B.

Then, a filler (spherical glass member) 20 is uniformly provided over the melted first resin layer 18 in the cavity 15, as shown in FIG. 2C. Thus, a region close to the surface of the first resin layer 18 contains a large amount of the filler 20. Consequently, the thermal expansion coefficient of the region close to the surface of the first resin layer 18 is lowered, thus a second resin layer 21 is formed over the first resin layer 18.

The amount of the filler 20 provided over the first resin layer 18 is adjusted so that the thermal expansion coefficient of the second resin layer 21 becomes, for example, substantially 2×10⁻⁶/° C. to 4×10⁻⁶/° C., preferably nearly equal to 3×10⁻⁶/° C. which is the thermal expansion coefficient of the semiconductor chip 8.

The filler 20 is substantially 50 μm, and the size of the filler 20 is selected according to a value of the thermal expansion coefficient of the second resin layer 21. Preferably, the filler 20 has a specific gravity smaller than that of the first rein layer 18. Thus, when provided over the first resin layer 18, the filler 20 gathers around the liquid surface of the first resin layer 18 to form the second resin layer 21.

Then, the upper mold on which the wiring motherboard is held by suction is lowered so that the semiconductor chip is immersed into the second resin layer 21. Then, two melted resin layers are thermally compressed by the upper and lower molds to form a seal 22 including the first resin layer 18 and the second resin layer 21 having a thermal expansion coefficient different from that of the first resin layer 18. In this case, the amount of the seal resin 17 and of the filler 20 are preliminarily adjusted so that the second resin layer 21 and the semiconductor chip 8 have the same thickness.

Then, the seal 22 covering the wiring motherboard 1 is thermally cured at a predetermined temperature of, for example, substantially 180° C. Thus, the seal 22 collectively covering the element formation units 2 is formed, as shown in FIG. 1C.

Thus, the first resin layer 18 having a thermal expansion coefficient nearly equal to that of the wiring motherboard 1 and the second resin layer 21 having a thermal expansion coefficient nearly equal to that of the semiconductor chip 8 form the seal 22, thereby preventing the wiring motherboard 1 from warping.

In other words, the semiconductor chip 8 and the second resin layer 21 are provided between the wiring motherboard 1 and the first resin layer 18. The semiconductor chip 8 and the second resin layer 21 have substantially the same thermal expansion coefficient. Therefore, the semiconductor chip 8 and the second resin layer 21 are thermally expanded and contracted in an integrated manner between the wiring mother board 1 and the first resin layer 18.

For this reason, the semiconductor chip 8 and the second resin layer 21 substantially uniformly apply distortion to the wiring motherboard 1 and the first resin layer 18, thereby preventing the wiring mother board 1 from warping.

Additionally, the first and second resin layers 18 and 21 are formed at the same time using the compression mold apparatus 12, thereby efficiently forming the seal 22 including two resin layers having different thermal expansion coefficients by one sealing process without increasing the number of manufacturing processes.

Further, the second resin layer 21 is formed by spaying the filler 20 over the upper surface of the first resin layer 18. Therefore, the connection strength between the first and second resin layers 18 and 21 does not degrade, thereby preventing a void between the first and second resin layers and preventing the first and second resin layers from peeling from each other.

Moreover, a seal resin does not have to be poured from a gate 23 and an air vent 24 shown in FIG. 2A, and the filler 20 is uniformly distributed in the second resin layer 21, thereby preventing the wiring motherboard 1 from warping after the seal 22 is formed due to the distribution bias, and preventing wires from flowing.

The two resin layers are formed by the MAP and provision of a filler, thereby enabling a versatile formation of the seal 22 irrespective of the size and the number of the wiring motherboard 1.

After the seal 22 is formed, the wiring motherboard 1 is subjected to a ball mounting process. Conductive solder balls 25 are mounted on the corresponding lands 5 provided in a grid on the surface 2b of the wiring motherboard 1 to form bump electrodes that will be external terminals, as shown in FIG. 1D.

Specifically, the solder balls 25 are held on suction holes of a suction apparatus 26, a flux is applied to the solder balls 25, and then the solder balls 25 are collectively mounted on the corresponding lands 5. After the solder balls 25 are mounted on every element formation unit 2, the wiring motherboard 1 is reflowed, and bump electrodes (external terminals) are therefore formed. As explained above, warpage of the wiring motherboard 1 is reduced, thereby enabling the solder balls 25 to be correctly mounted.

Then, the wiring motherboard 1 with the solder balls 25 is subjected to a dicing process and then diced along the dicing lines 3 into pieces of the element formation units 2, as shown in FIG. 1E.

Specifically, the wiring motherboard 1 on the side of the seal 22 is fixed on a dicing tape 27. Then, the wiring motherboard 1 is diced along the dicing lines 3 into pieces of the element formation units 2 using a dicing blade 28 of a dicing apparatus (not shown). After the dicing, each element formation unit 2 is detached from the dicing tape 27, and a semiconductor device 29 as shown in FIG. 3 is therefore obtained.

The semiconductor device 29 includes the seal 22 including the first and second resin layers 18 and 21. The second resin layer 21 covers a surface 30a of the wiring board 30 and side surfaces 8c of the semiconductor chip 8, and has a thermal expansion coefficient nearly equal to that of the semiconductor chip 8. The first resin layer 18 covers the semiconductor chip 8 and the second resin layer 21, and has a thermal expansion coefficient nearly equal to that of the wiring board 30.

According to the semiconductor device manufacturing method of the present invention, the seal 22 including the first and second resin layers 18 and 21 having different thermal expansion coefficients can be formed by one sealing process, thereby enhancing the manufacturing efficiency and lowering the costs.

It is apparent that the present invention is not limited to the above embodiments, but may be modified and changed without departing from the scope and spirit of the invention.

For example, although the case where the wiring motherboard 1 is a glass epoxy board has been explained in the embodiment, another wiring board, such as a flexible board made of a polyamide material, may be used. In the case of using the flexible board made of a polyamide material, a thermal expansion coefficient of the first resin layer is set to, for example, substantially 20×10⁻⁶/° C. to 25×10⁻⁶/° C. in accordance with the thermal expansion coefficient of the polyamide resin.

Additionally, the semiconductor device is not limited to the BGA semiconductor device, and may be an LGA (Land Grid Array) semiconductor device, or the like. Further, the present invention is applicable to MCP (Multi Chip Package) or SiP (System in Package) in which multiple semiconductor chips are mounted in one element formation unit.

The present invention is applicable to semiconductor device manufacturing industries.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

What is claimed is:

1. A method for a semiconductor device comprising:
forming a first seal layer in a cavity of a first mold, the first seal layer being in a liquid state;
forming a second seal layer over the first seal layer, the first seal layer being kept in the liquid state, and the second seal layer being in a liquid state;
immersing a semiconductor chip on a wiring board fixed on a second mold into the second seal layer; and
thermally curing the first and second seal layers.

2. The method according to claim 1, further comprising:
compressing the first and second molds after immersing the semiconductor chip.

3. The method according to claim 1, wherein thermally curing the first and second seal layers comprising thermally curing the first and second seal layers at the same time.

4. The method according to claim 1, wherein forming the second seal layer comprises uniformly spraying a filler over the first seal layer having a first specific gravity, the filler having a second specific gravity smaller than the first specific gravity.

5. The method according to claim 1, wherein the second seal layer and the semiconductor chip have the same thickness.

6. The method according to claim 1, wherein
the wiring board has a first thermal expansion coefficient;
the semiconductor chip has a second thermal expansion coefficient;
the first seal layer has a third thermal expansion coefficient nearly equal to the first thermal expansion coefficient; and
the second seal layer has a fourth thermal expansion coefficient nearly equal to the second thermal expansion coefficient.

7. The method according to claim 6, wherein the third thermal expansion coefficient ranges from 12×10⁻⁶/° C. to 14×10⁻⁶/° C.

8. The method according to claim 6, wherein the fourth thermal expansion coefficient ranges from 2×10⁻⁶/° C. to 4×10⁻⁶/° C.

9. A method for a semiconductor device comprising:
forming a first seal layer in a cavity of a first mold, the first seal layer being in a liquid state;
forming a second seal layer over the first seal layer, the first seal layer being kept in the liquid state, and the second seal layer being in a liquid state;
immersing a semiconductor chip on a wiring board fixed on a second mold into the second seal layer; and
thermally curing the first and second seal layers.

10. The method according to claim 9, further comprising:
compressing the first and second molds after immersing the semiconductor chip.

11. The method according to claim 9, wherein thermally curing the first and second seal layers comprising thermally curing the first and second seal layers at the same time.

12. The method according to claim 9, wherein forming the second seal layer comprises uniformly spraying a filler over the first seal layer having a first specific gravity, the filler having a second specific gravity smaller than the first specific gravity.

13. The method according to claim 9, wherein the second seal layer and the semiconductor chip have the same thickness.

14. The method according to claim 9, wherein
the wiring board has a first thermal expansion coefficient;
the semiconductor chip has a second thermal expansion coefficient;
the first seal layer has a third thermal expansion coefficient nearly equal to the first thermal expansion coefficient; and
the second seal layer has a fourth thermal expansion coefficient nearly equal to the second thermal expansion coefficient.

15. The method according to claim 14, wherein the third thermal expansion coefficient ranges from 12×10⁻⁶/° C. to 14×10⁻⁶/° C.

16. The method according to claim 14, wherein the fourth thermal expansion coefficient ranges from 2×10⁻⁶/° C. to 4×10⁻⁶/° C.

17. A method for a semiconductor device, the method comprising:
forming a first seal layer in a cavity of a first mold, the first seal layer being in a liquid state; and
forming a second seal layer over the first seal layer, the first seal layer being kept in the liquid state, and the second seal layer being in a liquid state.

18. The method according to claim 17, further comprising:
immersing a semiconductor chip on a wiring board fixed on a second mold into the second seal layer after forming the second seal layer; and
thermally curing the first and second seal layers.

19. The method according to claim 18, further comprising:
compressing the first and second molds after immersing the semiconductor chip.

20. The method according to claim 17, wherein forming the second seal layer comprises uniformly spraying a filler over the first seal layer having a first specific gravity, the filler having a second specific gravity smaller than the first specific gravity.
